(19) United States
(12) Patent Application Publication
(10) Pub. No.: US 2010/0256811 A1
(43) Pub. Date: Oct. 7, 2010

(54) DIAGNOSIS SYSTEM FOR TRANSPORT ROBOT

(76) Inventor: Yoshinori Fujii, Shizuoka (JP)

Correspondence Address: Tomoko Nakajima;Cermak Nakajima LLP, 127 S. Peyton Street, Suite 210, Alexandria, VA, 22314, US

(21) Appl. No.: 12/745,823

(22) PCT Filed: Dec. 26, 2008
(86) PCT No.: PCT/JP2008/073731

§ 371 Date: Jun. 25, 2010

(30) Foreign Application Priority Data
Dec. 27, 2007 (JP) 2007-337164

(51) Int. Cl. H01L 21/677; G05B 19/04

(52) U.S. Cl. 700/253

(57) ABSTRACT

There is provided a low-cost diagnosis system for a transport robot which is capable of improving the apparatus operating rate without incurring an increase in the number of parts. In case a robot arm is detected by any of detection means when a substrate (S) is transported by the robot arm among processing chambers (C), operation data of the robot arm to be detected by the detection means is obtained and reference value is prepared. Then, every time the robot arm is detected by the detection means, the operation data is obtained and compared with the reference value. In case a change exceeds a predetermined range, the transport robot is judged to be abnormal.

### TECHNICAL FIELD

The present invention relates to a low-cost diagnosis system for a transport robot, in which the diagnosis system utilizes a sensor for detecting the position of a substrate, the sensor being disposed in an existing processing apparatus.

### BACKGROUND ART

Conventionally, as an apparatus for performing various kinds of processing such as a film depositing process, etching process, and the like, there is known a processing apparatus (so-called cluster tool apparatus) which is constituted, as shown in FIG. 1, such that: a load lock chamber B for a substrate S and a plurality of processing chambers C are disposed to enclose a central transport chamber A having disposed therein a transport robot 1; and that the substrate S introduced by the transport robot 1 into the load lock chamber B is transported to and from each of the processing chambers C or among the respective processing chambers C.

The transport robot 1 is provided with a robot arm 11, and a driving means for driving the robot arm 11 so as to be swung and telescopically moved (extended or contracted) on the same plane. At a front end of the robot arm 11 there is provided a robot hand 12 for supporting the substrate S in a state of being placed thereon.

In this kind of transport robot 1, it is necessary for the robot hand 12: to appropriately hold the substrate S which is located in a predetermined position; to transport the substrate S to an intended position (e.g., to a substrate stage (not illustrated) of each processing chamber C); and to transfer the substrate S to an appropriate position. For this purpose there is provided a detection means 2 such as an optical sensor and the like at a ceiling portion or a bottom portion in a border region of the transport chamber A relative to each of the processing chambers C (see FIG. 1(b)).

In case the substrate S is transported to the intended position, confirmation is made by the detection means 2, aside from the confirmation of the presence or absence of the substrate S, as to whether the substrate S is being held by the robot hand 12 with accuracy. In case a positional deviation of the substrate S has been found, the motion of the robot arm 11 is adjusted so as to cancel the amount of the positional deviation (see, e.g., patent document 1).

By the way, the above positional deviation of the substrate is sometimes attributable to the breakdown of the robot arm and parts such as motors and bearings which constitute the diving means for driving the robot arm. In such a case, even if the motion of the robot arm is adjusted at a specific position, the positional deviation comes to occur due to deterioration in measurement accuracy and in accuracy of operation to cancel the positional deviation. If the transport robot is left as it is with the positional accuracy thereof being lowered, it will give rise to the poor quality of the product processing and the mechanical troubles in the apparatus, thereby incurring increased losses. On the other hand, in order to prevent the apparatus operating rate from getting lowered, it is preferable to carry out maintenance on schedule by taking advance notice of the mechanical trouble. However, if separate parts such as sensors and the like are provided in order to judge the normality of the transport robot, not only becomes the constitution of the apparatus complicated, but also becomes the cost thereof high.

Patent document 1: JP-A-2007-27378

### DISCLOSURE OF THE INVENTION

### Problems to be Solved by the Invention

Therefore, in view of the above points, this invention has a problem in providing a diagnosis system for a low-cost transport robot which improves the apparatus operating rate without incurring an increase in the number of parts.

### Means for Solving the Problems

In order to solve the above problems, the diagnosis system for a transport robot according to this invention comprises: a transport robot having a robot arm with a robot hand at a front end thereof for supporting a substrate to be processed, the transport robot having a driving means for driving the robot arm; and at least one detection means disposed to detect the substrate supported by the robot hand when the substrate is transported by the robot arm among a plurality of processing chambers. When a predetermined portion of the robot arm is detected by the detection means while transporting the substrate by the robot arm among the plurality of processing chambers, a reference value is prepared by obtaining operation data of the robot arm to be detected by the detection means. When the predetermined portion of the robot arm is detected by the detection means, an operation data at that time is obtained, and the operation data is compared with the reference value to judge that the transport robot is abnormal if a change exceeds a predetermined range.

According to this invention, in a processing apparatus in which a plurality of processing chambers are provided for carrying out various processing works therein, considering the fact that the robot arm provided with the robot hand to support the substrate is detected by crossing the detection means which is disposed to detect the presence of, or the position of, the substrate when the substrate is transported by the transport robot, the detection means is utilized to judge the normality of the transport robot.

In other words, when the predetermined portion of the robot arm is detected by any of the detection means, the operation data of the robot arm at the time of detection by the detection means is obtained, and a reference value is prepared. Then, at the time, e.g., when the above predetermined portion is detected by the detection means during the predetermined prescribed movement such as initializing movement and the like of the transport robot, or during various kind of processing (manufacturing) of the substrate, the then operation data is obtained. This operation data and the above reference value are compared with each other. If a change takes place by exceeding the predetermined range, judgment is made that the transport robot is abnormal.

As described above, according to this invention, the normality of the transport robot can be easily judged by making use of the existing elements. Therefore, without increase in the number of constituent parts, the cost can be reduced. In addition, when the transport robot is operated to the predetermined position, judgment of the normality of the transport robot is made. Therefore, the signs of occurrence of abnormality can be grasped at an early date, thereby enabling scheduled maintenance and, as a result, the improvement in the apparatus operating rate can be improved.

In addition, according to this invention, there may be employed a constitution in which the robot arm is driven so as to be swingable and extended or contracted on at least the same plane, and in which the detection means is an optical sensor which is disposed to throw (project) light in a direction perpendicular to the plane. This invention can be applied to an example in which the robot arm is constituted to be movable up and down in order to hand over, e.g., the substrate.

There may be employed a constitution in which the driving means is a motor provided with an encoder so arranged that, when the predetermined portion of the robot arm is detected by the detection means, the operation data is obtained from the address in the encoder.

On the other hand, the operation data can be obtained based on a time after the predetermined portion of the robot arm has been detected by any of the detection means to the time when the predetermined portion of the robot arm is detected by another detection means, or based on a time from an order to start operation of the transport robot to a time when the predetermined portion of the robot arm is detected by any of the detection means.

In order to improve the rate of operation, it is preferable to make the judgment of abnormality of the transport robot when the predetermined prescribed operation is being performed. Here, the prescribed operation includes the operations to be performed based on a predetermined operation program such as initializing operation of the transport robot, and the like, aside from the operations of transporting the substrate for various kind of processing on the substrate.

In the transport robot to be used in a cluster tool apparatus, when the predetermined portion of the robot arm is detected, only the predetermined operation data may be obtained by extraction. In this manner, by determining the detection means which serves as a reference in judgment of normality of the transport robot, the control for the judgment can be made simplified.

Further, in case the robot arm is movable up and down, the judgment of the transport robot may be made at a predetermined height. In this case, by judging the abnormality of the transport robot at the same height, the signs of mechanical troubles may be caught from the inclination of the robot arm and the robot hand relative to the optical axis of the optical sensor.

### BEST MODE FOR CARRYING OUT THE INVENTION

Now, with reference to the processing apparatus as shown in FIG. 1, a description will now be made of an embodiment to which this invention is applied. In other words, the transporting chamber A is provided with a transport robot 1 of a known construction, and a detection means 2 is provided in the neighborhood of a connection portion to each of the processing chambers C.

As the detection means 2 there are used optical sensors of a known construction such as a laser sensor, an LED fiber sensor, and the like. In this case, the detection means 2 is disposed such that light is projected vertically relative to a robot arm which is driven to swing and telescopically move on the same plane. The detection means 2 is of a translucent type which is made up of a photo-transmitter 21 and a receiver 22. It is also possible to use a reflection type of detection means.

A description will now be made with reference to FIG. 2. The transport robot 1 has two motors as driving means (not illustrated). The rotating shafts 10a, 10b of the respective motors are disposed coaxial with each other. Each of the rotating shafts 10a, 10b has connected thereto the robot arm 11 so as to constitute a link mechanism. The robot arm 11 has a robot hand 12 at a front end thereof through a gear box G. By appropriately controlling the rotation angle of the rotating shafts 10a, 10b of the respective motors, the robot arm 11 and the robot hand 12 can be freely expanded or contracted and swingable. It may alternatively be so arranged that a lifting means is provided such as an air cylinder and the like for the rotating shaft of each of the motors so as to make the robot arm 11 itself movable up and down (ascended and descended). In this embodiment, the data processing and the like of the operation of the transport robot 1 and the result of detection by the detection means 2 are arranged to be central-controlled by a control means (not illustrated).

Since the substrate S has a possibility of being heated to a high temperature in the processing chambers C, the robot arm 11 and the robot hand 12 are made of materials having heat resistance, e.g., of plate materials of Al-alloy, Al₂O₃, SiO₂, SiC, and the like. Further, the robot hand 12 is provided with a pair of finger portions 14 which extend forward by bifurcating from a base portion 13 that is connected to the robot arm 11. The base portion 13 and the front end portions 14 of both the finger portions 14 are provided with seating surfaces 15 on which the bottom peripheral surface of the substrate S can be seated at three points in the peripheral direction. The substrate S is thus supported in such a manner that the bottom surface other than the peripheral portion is floated off from the robot hand 12.

After the substrate S has thus been supported by the robot hand 12, the robot arm 11 is extended or contracted and is swung so that the substrate S charged to the load lock chamber B is transported to any one of the processing chambers C or so that the substrate S is transported among the respective processing chambers C. When the substrate S is transferred to an intended position, confirmation is made by any one of the detection means 2 as to whether the substrate S is present or not, or as to whether the substrate S is supported by the robot hand 13 with high accuracy or not.

Here, a description will be made of an example in which the substrate S is transported by the transport robot 1 from the first processing chamber C1 to the second processing chamber C2. From a standby position in which the robot arm 11 is in a contracted state and in which the front end of the finger portion 14 is directed toward the first processing chamber C1, the robot arm 11 is extended to thereby receive a substrate S from the first processing chamber C1, and then return the robot arm 11 to the standby position. The robot arm 11 is then swung until it reaches a position in which the front end of the finger portion 15 is directed toward the second processing chamber C2. Then, the robot arm 11 is extended to thereby hand over the substrate S from the first processing chamber C1, and then return the robot arm 11 to the original state (standby position) (see FIG. 3).

During the time in which the substrate S is being transported to the intended position, the robot arm 11 inclusive of the robot hand 12 will respectively cross each of the detection positions 2a, 2b of the detection means 2 which are provided in the transporting chamber A near the connecting portions between the transporting chamber A and the first processing chamber C1 and the second processing chamber C2, respectively. Therefore, in a position on an orbit which crosses the detection position of the detection means 2 when the robot 1 is operated, the base end portion 13 and both the finger portions 14 of the robot hand 12 have respectively formed therein through holes 17, 18 which constitute predetermined portions to be detected by the detection means 2 (see FIG. 2). Then, when, e.g., the robot arm 11 is swung, the signal of the detection means 2 will become OFF at the beginning when the robot hand 12 crosses the detection position, but the signal will become ON when any one of the through holes 17, 18 reaches the detection position. Finally, when the robot arm 13 has completely crossed the detection position, the signal of the detection means 2 becomes OFF again.

By taking advantage of this kind of switching of the signal in the detection means 2, operation data of the transport robot 1 is obtained to prepare a reference value. This operation data is obtained based on the timing of switching of the signal in each of the detection means 2a, 2b when the robot hand 12 is moved from the first processing chamber C1 to the second processing chamber C2 at normal time. In other words, the operation data is obtained based on the time from the detection timing of one of the detection means 2a to the detection timing of the other detection means 2b (in this case, the operation data serving as the reference value is an identification number that is allotted to, e.g., each detection means, and its elapsed time; they are kept registered in the control means). Then, when the predetermined portion of the robot hand 12 of the transport robot 1 is successively detected by both the detection means 2a, 2b, the then actual operation data (time) is obtained. The operation data at this time is compared with the reference value by the control means. In case the data has changed beyond a predetermined range, the transport robot 1 is judged to be abnormal.

In the above example, the operation data as the reference value is prepared based on the elapsed time from the detection timing of the one detection means 2a. The operation data as the reference value may alternatively be prepared based on the elapsed time from the time point of starting the operation of the motor to the time point of detection by any one of the detection means 2a, 2b.

Further, the operation data as the reference value may be prepared based on the relationship between the elapsed time from the detection timing of one detection means 2a to the detection timing of the other detection means 2b, and the rotational speed of the motor (data on swing speed and extension/contracting speed) (in this case, data can be prepared by, e.g., replacing the elapsed time and the speed with the moving distance, and the data can be registered in the control means). At the time when the predetermined portion of the robot hand 12 of the transport robot 1 is successively detected by both the detection means 2a, 2b, if the change occurs beyond a predetermined range, it may be judged that the transport robot 1 is abnormal.

Still furthermore, a description has so far been made of an example in which judgment is made of the normality of the transport robot based on the timing of switching the signal of the detection means 2 at each of the detection means 2a, 2b. However, it need not be limited to the above example. For example, in case the motor as the driving means is provided with an encoder, the operation data as the reference value may be obtained from encoder coordinates or encoder value (address) at the time when the predetermined portion of the robot arm 11 or robot hand 12 is detected by any of the detection means 2a or 2b. Then, a comparison is made between the encoder coordinates or the encoder value when the above predetermined portion has been detected by the same detection means, and the operation data as the reference value. In case the data has changed beyond a predetermined range, the transport robot 1 is judged to be abnormal.

In case the robot arm 11 itself is constituted to be movable up and down, it may be so arranged that the transport robot 1 is judged to be normal or not at a height position that is set in advance. If the normality of the transport robot 1 is judged at the same height position as described above, an inclination of the robot arm 11 or the robot hand 12 will change relative to an optical axis of an optical sensor as the detection means 2 due to deterioration of constituent parts such as bearings and the like at the time when the robot arm 11 is swung or extended or contracted. As a result, the time until the detection is made by the detection means 2 will change, so that the advance signs of mechanical trouble can be brought to attention.

Here, the judgment of normality (or abnormality) of the above transport robot 1 can be made when the robot hand 12 does not support the substrate S during the predetermined prescribed operations such as initializing operation and the like of the transport robot. However, in case that predetermined portion of the robot arm 11 which is to be detected by the detection means 2 is detected by any one of the detection means 2 during the time when the substrate S is being transported from one processing chamber to another processing chamber during various processing to (manufacturing of) the substrate S, a judgment can be made of the normality of the transport robot 1 even during the various processing to (manufacturing of) the substrate S. It is to be noted that the predetermined portion of the robot arm 11 to be detected by the detection means 2 need not be limited to the above through holes 17, 18. For example, it may be constituted by a notch formed in an end portion whose surface is exposed even in a state in which the substrate S is supported by the robot hand 12.

In case the transport robot 2 has two robot arms 11 that are coupled to the rotating shafts 10a, 10b, both the robot arms will come to perform the swinging movement and extension or contraction movement at the same time. At this time, either of the detection means 2 will come to simultaneously detect the predetermined portions of both the robot arms. As a result, there is a possibility that the amount of data increases and that the control to judge the normality becomes complicated. On the other hand, in a cluster tool apparatus, also in case there are a plurality of processing chambers (e.g., eight), there will occur the similar problems if the detection of the predetermined portion of the robot arm is performed for every detection means 2.

As a solution, like in the case in which the robot arm 11 is detected by the detection means 2b when the substrate S is transported from the first processing chamber C1 to the second processing chamber C2, the normality of the transport robot 1 may be judged by extracting to obtain only particular operation data when the transport robot 1 performs the particular operations and by thus determining the detection means which becomes standard for judging the normality of the transport robot 1. In this case, each of the detection means 2 and the two motors are assigned in registering identification numbers to the control means. Then, the particular operation data may be prepared only in relation to the selected identification numbers out of those registered ones.

As described hereinabove, it becomes possible to judge the normality of the transport robot 1 by making use of the detection means 2 for detecting the substrate position, the detection means 2 being provided as a piece of equipment of the existing processing apparatus 1. As a result, a low cost can be attained without incurring an increase in the number of parts. In addition, the sign of occurrence of abnormality can be grasped at an early stage to thereby enable a systematic (scheduled) maintenance. As a consequence, the apparatus operating rate can be improved.

In the above embodiment, a description has been made of an example in which the substrate S is transported by the transport robot 1 from the first processing chamber C1 to the second processing chamber C2. Without being limited thereto, this invention is applicable to an existing processing apparatus in which detection means is provided to make detection by the detection means 2 when the transport robot 1 is operated.

Furthermore, in the above embodiment, a description has been made mainly of judgment of normality during prescribed motion or during manufacturing. The following is also possible, namely, in a position in which the through hole 17 formed in the robot hand 12 crosses the detection position 2a or 2b of each of the detection means 2, the robot arm 11 is extended or contracted and swung to thereby obtain a position in which the signal is switched ON or OFF by each of the detection means 2a, 2b. Based on an average value of an encoder address at the time the signal is switched ON or OFF, the center of the through hole 17 is identified or specified. By thus periodically performing the identification of the center of this kind of through hole 17, it becomes possible also to detect the occurrence of positional deviation of the robot hand 12 relative to the robot arm 11 upon receipt by the robot hand 12 of shocks and the like.

### BRIEF DESCRIPTION OF THE DRAWINGS

FIG. 1(a) and FIG. 1(b) are plan view and a sectional view, respectively, schematically showing a substrate processing apparatus provided with a transport robot;

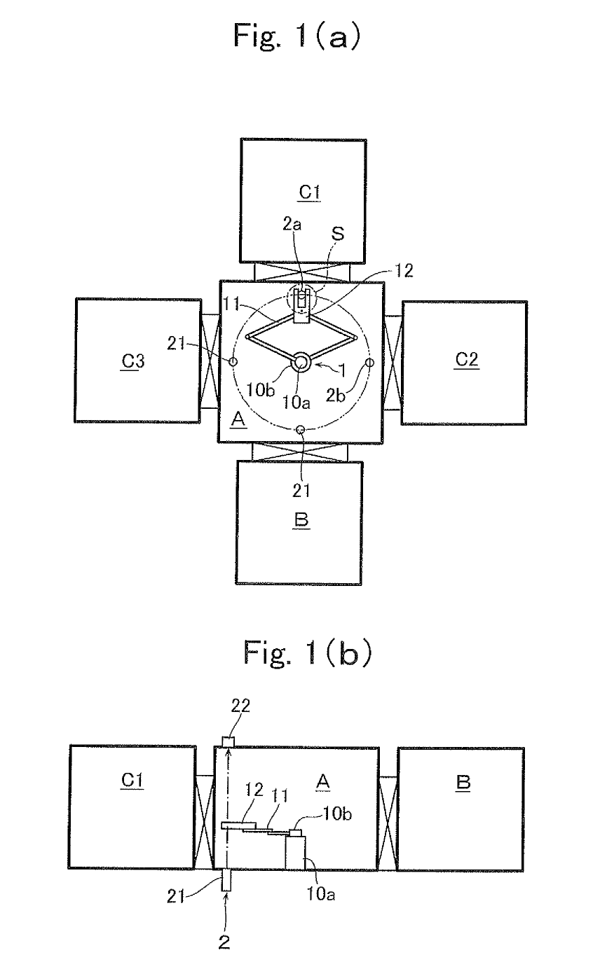

FIG. 2 is a plan view showing a robot hand according to an embodiment of this invention; and

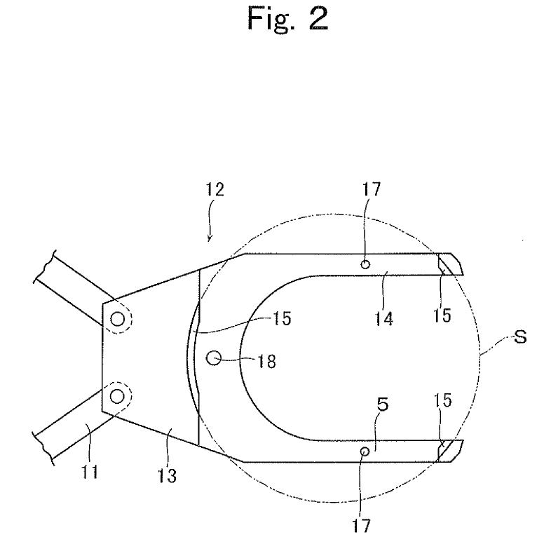

FIG. 3 is a schematic plan view explaining the transportation of the substrate by the robot hand between processing chambers.

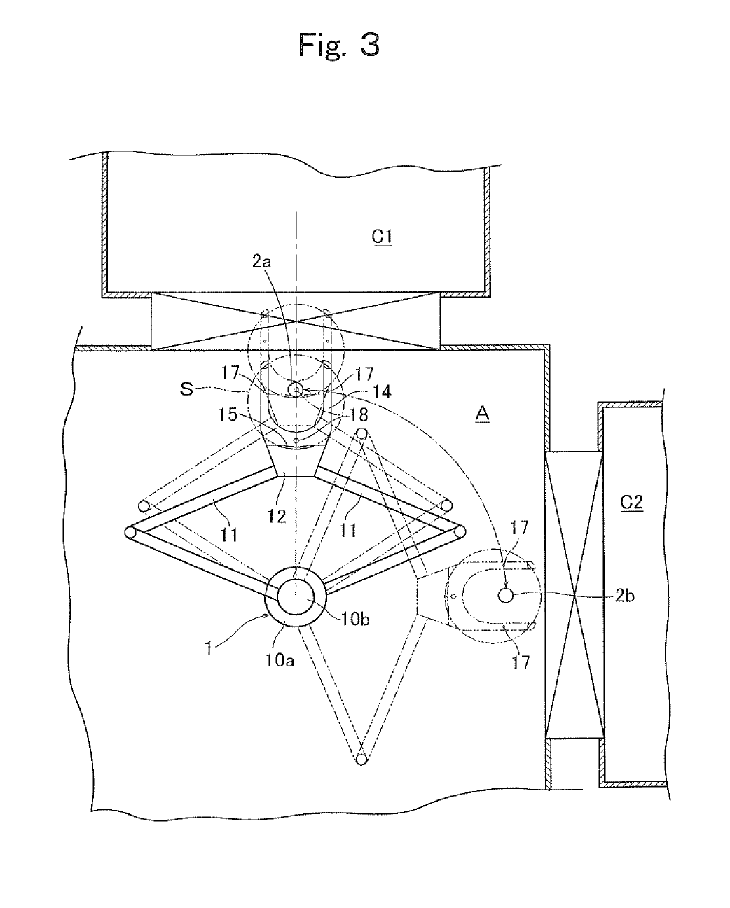

### DESCRIPTION OF REFERENCE NUMERALS AND CHARACTERS

11 robot arm

12 robot hand

2 detection means

2a, 2b detection position

S substrate

A load lock chamber

C processing chamber

1. A diagnosis system for a transport robot, the diagnosis system comprising:
a transport robot having a robot arm with a robot hand at a front end thereof for supporting a substrate to be processed, the transport robot having a driving means for driving the robot arm;
at least one detection means disposed to detect the substrate supported by the robot hand when the substrate is transported by the robot arm among a plurality of processing chambers,
wherein, when a predetermined portion of the robot arm is detected by the detection means while transporting the substrate by the robot arm among the plurality of processing chambers, a reference value is prepared by obtaining operation data of the robot arm to be detected by the detection means;
wherein, when the predetermined portion of the robot arm is detected by the detection means, an operation data at that time is obtained, and
wherein the operation data is compared with the reference value to judge that the transport robot is abnormal if a change exceeds a predetermined range.

2. The diagnosis system for a transport robot according to claim 1,
wherein the robot arm is driven so as to be swingable and extended or contracted on at least a same plane, and
wherein the detection means is an optical sensor which is disposed to throw light in a direction perpendicular to the plane.

3. The diagnosis system for a transport robot according to claim 1,
wherein the driving means is a motor provided with an encoder, and
wherein the operation data is obtained based on an address of the encoder when the predetermined portion of the robot arm is detected by the detection means.

4. The diagnosis system for a transport robot according to claim 1, wherein the operation data is obtained based on a time after the predetermined portion of the robot arm has been detected by any of the detection means to the time when the predetermined portion of the robot arm is detected by another detection means, or based on a time from an order to start operation of the transport robot to a time when the predetermined portion of the robot arm is detected by any of the detection means.

5. The diagnosis system for a transport robot according to claim 1, wherein the judgment of abnormality of the transport robot is made when the predetermined prescribed operation is being performed.

6. The diagnosis system for a transport robot according to claim 1, wherein, in case the predetermined portion of the robot arm is detected, only the predetermined operation data is obtained by extraction.

7. The diagnosis system for a transport robot according to claim 1, wherein the robot arm is movable up and down and wherein the judgment of the transport robot is made at a predetermined height.
